(19) United States
(12) Patent Application Publication
(10) Pub. No.: US 2025/0044355 A1
(43) Pub. Date: Feb. 6, 2025

(54) SWITCH WITH SERVICE LIFE INDICATOR

(71) Applicant: HONEYWELL INTERNATIONAL INC., Charlotte, NC (US)

(72) Inventors: Fu XIANG, Charlotte, NC (US); Yongbing ZHU, Charlotte, NC (US); Bo ZHANG, Charlotte, NC (US); Xiao Lin BAI, Charlotte, NC (US); Xiaoqiang ZHANG, Charlotte, NC (US)

(21) Appl. No.: 18/769,598

(22) Filed: Jul. 11, 2024

(30) Foreign Application Priority Data
Jul. 31, 2023 (CN) 202310952084.8

(51) Int. Cl. G01R 31/327; G01R 27/20; H01H 1/00; H01H 1/20; H01H 3/12

(52) U.S. Cl. CPC G01R 31/3275; G01R 27/205; G01R 31/3274; H01H 1/0015; H01H 1/2025; H01H 3/12

(57) ABSTRACT

A switch is provided. The switch includes, but not limited to: normally open (NO) terminals; normally closed (NC) terminals; an actuator, configured to conduct at least one of the NO terminals and the NC terminals; an indicator for a remaining service life of the switch; and a controller component, configured to: determine the remaining service life of the switch based on a conduct resistance between at least one of the NO terminals and the NC terminals, and control the indicator to illuminate a corresponding color based on the determined remaining service life of the switch.

### CROSS-REFERENCE TO RELATED APPLICATIONS

This application claims priority pursuant to 35 U.S.C. 119 (a) to Chinese Application No. 202310952084.8, filed Jul. 31, 2023, which application is incorporated herein by reference in its entirety.

### FIELD OF THE INVENTION

Exemplary embodiments of the present disclosure relate generally to a switch, and more particularly, in some examples, to a switch with a service life indicator.

### BACKGROUND

Applicant has identified many technical challenges and difficulties associated with visualizing service life of switches. Through applied effort, ingenuity, and innovation, Applicant has solved problems relating to improving the usage of the switches by developing solutions embodied in the present disclosure, which are described in detail below.

### BRIEF SUMMARY

Various embodiments described herein relate to switches with service life indicators.

In accordance with various embodiments of the present disclosure, a switch is provided. The switch includes, but not limited to: normally open (NO) terminals; normally closed (NC) terminals; an actuator, configured to conduct at least one of the NO terminals and the NC terminals; an indicator for a remaining service life of the switch; and a controller component, configured to: determine the remaining service life of the switch based on a conduct resistance between at least one of the NO terminals and the NC terminals, and control the indicator to illuminate a corresponding color based on the determined remaining service life of the switch.

In some embodiments, to determine the remaining service life of the switch, the controller component is configured to: measure a first contact resistance between the NO terminals in an instance in which the actuator conducts the NO terminals; and determine the remaining service life of the switch based on the first contact resistance.

In some embodiments, to determine the remaining service life of the switch, the controller component is configured to: measure a second contact resistance between the NC terminals in an instance in which the actuator conducts the NC terminals; and determine the remaining service life of the switch based on the second contact resistance.

In some embodiments, the actuator includes a pin and a bridge fixed on the pin, where the bridge is configured to conduct the NO terminals or the NC terminals.

In some embodiments, the switch further includes a guiding element, where the pin is configured to move through an aperture of the guiding element.

In some embodiments, the actuator further includes a spring positioned adjacent to the pin and configured to facilitate movement of the actuator.

In some embodiments, the NO terminals include a first terminal and a second terminal, where the actuator conducts the first terminal and the second terminal in an instance in which the actuator conducts the NO terminals.

In some embodiments, the switch further includes a first contact electrically connected with the first terminal; and a second contact electrically connected with the second terminal.

In some embodiments, the actuator conducts the first contact and the second contact in an instance in which the actuator conducts the NO terminals.

In some embodiments, the NC terminals include a third terminal and a fourth terminal, where the actuator conducts the third terminal and the fourth terminal in an instance in which the actuator conducts the NC terminals.

In some embodiments, the switch further includes: a third contact electrically connected with the third terminal; and a fourth contact electrically connected with the fourth terminal.

In some embodiments, the actuator conducts the third contact and the fourth contact in an instance in which the actuator conducts the NC terminals.

In accordance with another embodiment of the present disclosure, a switch is provided. The switch includes, but not limited to: normally open (NO) terminals; normally closed (NC) terminals; an actuator, configured to conduct at least one of the NO terminals and the NC terminals; an indicator for a remaining service life of the switch; a sensor, configured to detect the actuator in an instance in which the actuator is pressed; and a controller component, configured to: determine the remaining service life of the switch based on times that the actuator is pressed, and control the indicator to illuminate a corresponding color based on the determined remaining service life of the switch.

In some embodiments, the sensor is an optoelectronic switch.

In some embodiments, the sensor includes: an emitter; and a receiver, where the emitter is configured to generate a beam and direct the beam to the receiver, and the receiver is configured to receive the beam and detect an interruption of the beam.

In some embodiments, the interruption of the beam is detected in an instance in which the actuator is pressed.

In some embodiments, to determine the remaining service life of the switch, the controller component is configured to: record a historical pressing times that the actuator is pressed; and determine the remaining service life of the switch based on the historical pressing times.

In accordance with another embodiment of the present disclosure, a switch is provided. The switch includes, but not limited to: normally open (NO) terminals; normally closed (NC) terminals; an actuator, configured to conduct at least one of the NO terminals and the NC terminals; an indicator for a remaining service life of the switch; a counting module, configured to count times that the actuator conducts the NO terminals; and a controller component, configured to: determine the remaining service life of the switch based on times that actuator conducts the NO terminals, and control the indicator to illuminate a corresponding color based on the determined remaining service life of the switch.

In some embodiments, to determine the remaining service life of the switch, the controller component is configured to: record a historical conducting times that the actuator is conducting the NO terminals; and determine the remaining service life of the switch based on the historical conducting times.

In some embodiments, to determine the remaining service life of the switch, the controller component is configured to: record a historical conducting times that the actuator is conducting the NC terminals; and determine the remaining service life of the switch based on the historical conducting times.

The foregoing illustrative summary, as well as other exemplary objectives and/or advantages of the disclosure, and the manner in which the same are accomplished, are further explained in the following detailed description and its accompanying drawings.

### BRIEF DESCRIPTION OF THE DRAWINGS

The description of the illustrative embodiments may be read in conjunction with the accompanying figures. It will be appreciated that, for simplicity and clarity of illustration, elements illustrated in the figures have not necessarily been drawn to scale, unless described otherwise. For example, the dimensions of some of the elements may be exaggerated relative to other elements, unless described otherwise. Embodiments incorporating teachings of the present disclosure are shown and described with respect to the figures presented herein, in which:

FIG. 1A and FIG. 1B illustrate exemplary diagrams depicting an example switch, in accordance with various embodiments of the present disclosure;

FIG. 2A and FIG. 2B illustrate exemplary diagrams depicting an example switch, in accordance with various embodiments of the present disclosure;

FIG. 3 illustrates an exemplary diagram illustrating an example sensor, in accordance with various embodiments of the present disclosure;

FIG. 4A and FIG. 4B illustrate exemplary diagrams depicting an example switch, in accordance with various embodiments of the present disclosure;

FIG. 5 illustrates an exemplary electrical diagram depicting an example switch, in accordance with various embodiments of the present disclosure;

FIG. 6 illustrates an exemplary block diagram depicting an example switch, in accordance with various embodiments of the present disclosure; and

FIG. 7 illustrates an exemplary diagram depicting an example controller component, in accordance with various embodiments of the present disclosure;

### DETAILED DESCRIPTION OF THE INVENTION

Some embodiments of the present disclosure will now be described more fully hereinafter with reference to the accompanying drawings, in which some, but not all embodiments of the disclosure are shown. Indeed, these disclosures may be embodied in many different forms and should not be construed as limited to the embodiments set forth herein; rather, these embodiments are provided so that this disclosure will satisfy applicable legal requirements. Like numbers refer to like elements throughout.

As used herein, terms such as “front,” “rear,” “top,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances.

As used herein, the term “comprising” means including but not limited to and should be interpreted in the manner it is typically used in the patent context. Use of broader terms such as “comprises”, “includes”, and “having” should be understood to provide support for narrower terms such as “consisting of”, “consisting essentially of”, and “comprised substantially of”.

The phrases “in one embodiment,” “according to one embodiment,” and the like generally mean that the particular feature, structure, or characteristic following the phrase may be included in at least one embodiment of the present disclosure, and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

The terms “electronically coupled” or “in electronic communication with” in the present disclosure may refer to two or more electrical elements (for example, but not limited to, an example processing circuitry, communication module, input/output module, memory) and/or electric circuit(s) being connected through wired means (for example, but not limited to, conductive wires or traces) and/or wireless means (for example, but not limited to, wireless network, electromagnetic field), such that electronic indications, signal or the like data and/or information (for example, electronic indications, signals) may be transmitted to and/or received from the electrical elements and/or electric circuit(s) that are electronically coupled.

The term “switch” in the present disclosure may refer to an electrical component, limit switch or electromechanical device that can be configured to connect or disconnect a conducting path in an electrical circuit such that an electrical current flowing along the conducting path is interrupted or diverted. An example switch may be used in a variety of applications to control electrical circuits. For example, the example switch may comprise a bridge to conduct contacts. In various applications, when the bridge and corresponding contacts are in a closed state (i.e., make contact with one another), an electrical current may pass between them. In contrast, when the bridge and corresponding contacts are in an open state (i.e., not in contact with one another), no electrical current passes between them.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

Various example embodiments address exemplary technical problems associated with visualizing service life of switches. As understood by those of skill in the field to which the present disclosure pertains, for example, switches may be replaced periodically in accordance with a predetermined schedule. In some examples, switches may therefore be replaced before they have reached the end of their service life. Thus, waste is associated with the premature replacements and, as a result, the usage of switches are not optimized in some examples. Therefore, there's a need to determine and visualize the remaining service life of the switches.

To address at least these exemplary problems as well as others, example switches described herein improve, in some examples, the usage of switches by providing a visualization of the remaining service life of the example switches. For example, a switch may include an indicator for the remaining service life of the switch. In some examples, the switch may further include a controller component, configured to determine the remaining service life of the switch, and, in some examples, the controller component may be configured to control the indicator to illuminate in a corresponding color or otherwise provide a signal or indication based on the remaining service life of the switch.

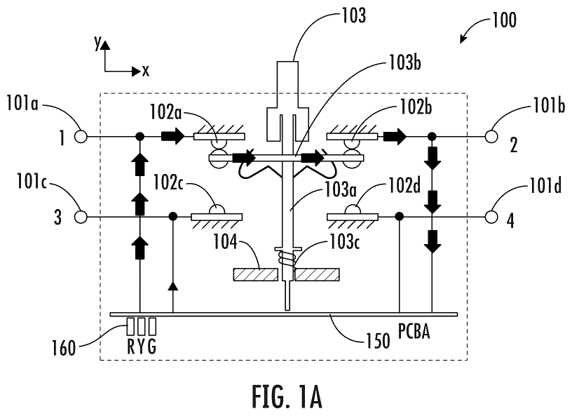

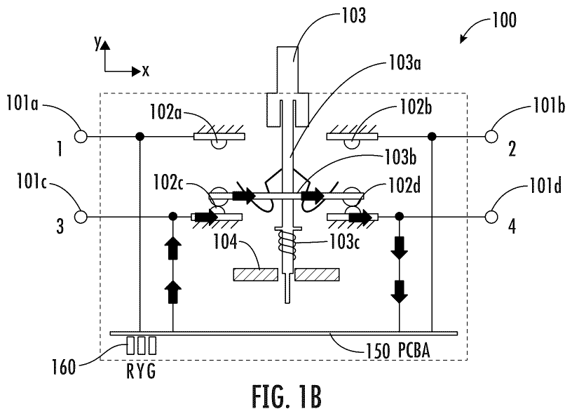

Referring now to FIG. 1A and FIG. 1B, example diagrams illustrating an example switch 100 in accordance with some example embodiments described herein are provided. As illustrated in FIG. 1A and FIG. 1B, the example switch 100 may comprise a first terminal 101a, a second terminal 101b, a first contact 102a electrically connected with the first terminal 101a, a second contact 102b electrically connected with the second terminal 101b.

In some embodiments, the example switch 100 may further comprise a third terminal 101c, a fourth terminal 101d, a third contact 102c electrically connected with the third terminal 101c, a fourth contact 102d electrically connected with the fourth terminal 101d.

In some embodiments, the example switch 100 may further comprise an actuator 103 and a guiding element 104. For example, the actuator 103 may be confined and/or guided to move through an aperture (e.g., a slot, a groove, or the like) of the guiding element 104. In some examples, the actuator 103 may comprise a pin 103a, a bridge 103b fixed on the pin 103a, and a spring 103c. For example, the spring 103c may be positioned adjacent to the pin 103a and may operate to facilitate movement of the actuator 103. For example, the actuator 103 may be configured to move vertically (e.g., in a y direction).

In some embodiments, the guiding element 104 may be positioned adjacent to one end of the pin 103a.

In some examples, the first terminal 101a and the second terminal 101b may be normally open (NO) terminals. For example, the first terminal 101a and the second terminal 101b may be normally open, such that no current can flow between the first terminal 101a and the second terminal 101b until the bridge 103b of the actuator 103 is connecting the first contact 102a and the second contact 102b.

In some examples, the third terminal 101c and the fourth terminal 101d may be normally closed (NC) terminals. For example, the third terminal 101c and the fourth terminal 101d may be normally closed, such that a current can flow between the third terminal 101c and the fourth terminal 101d until the bridge 103b of the actuator 103 is disconnected with the third contact 102c and the fourth contact 102d.

In some examples, the actuator 103 may be configured to move vertically (e.g., in a y direction) to conduct at least one of the NO terminals and the NC terminals.

In some examples, as shown in FIG. 1A, the bridge 103b may be in contact with the first contact 102a and the second contact 102b when the actuator 103 is pressed, such that the bridge 103b of the actuator 103 is conducting the NO terminals (or the first contact 102a and the second contact 102b). In some examples, as shown in FIG. 1B, the bridge 103b may be in contact with the NC terminals (or the third contact 102c and the fourth contact 102d) when the actuator 103 is released, such that the bridge 103b of the actuator 103 is conducting the NC terminals (or the third contact 102c and the fourth contact 102d).

In some examples, repeatable switching actions (e.g., pressing and releasing) may be performed by pressing the actuator 103 and releasing the actuator 103.

In some embodiments, the example switch 100 may further comprise a controller component 150, such as a printed circuit board assembly (PCBA), to communicate with the first contact 102a, the second contact 102b, the third contact 102c, and the fourth contact 102d. An example PCBA may be or include epoxy, ceramic, alumina, LCPs, combinations thereof, and/or the like. For example, wire may be utilized to electrically connect the first contact 102a, the second contact 102b, the third contact 102c, and the fourth contact 102d to the PCBA.

In some embodiments, the controller component 150 may be configured to measure a first contact resistance between the NO terminals (or the first contact 102a and the second contact 102b) when the actuator 103 is pressed. For example, as shown in FIG. 1A, the controller component 150 may be configured to measure the first contact resistance when the actuator 103 is pressed and the bridge 103b of the actuator 103 is conducting the NO terminals (or the first contact 102a and the second contact 102b).

In some embodiments, the controller component 150 may be configured to determine a remaining service life of the example switch 100 based on the first contact resistance.

In some examples, the first contact resistance between the NO terminals (or the first contact 102a and the second contact 102b) may be within a first range. The first range may be derived based on a predetermined data, may be learned such as via supervised or unsupervised learning, may be derived statistically based on testing, and/or the like. For example, the first range may be 0-45 mΩ. In some examples, a remaining service life of the example switch 100 may be within a range that is based on a predetermined data, may be learned such as via supervised or unsupervised learning, may be derived statistically based on testing, and/or the like. In some examples, the remaining service life may be from about 1000K to about 1500K when the first contact resistance between the NO terminals (or the first contact 102a and the second contact 102b) is within the first range.

In some examples, the first contact resistance between the NO terminals (or the first contact 102a and the second contact 102b) may be within a second range. The second range may be derived based on a predetermined data, may be learned such as via supervised or unsupervised learning, may be derived statistically based on testing, and/or the like. For example, the second range may be 45 mΩ-100 mΩ. In some examples, the remaining service life of the example switch 100 may be within a range that is based on a predetermined data, may be learned such as via supervised or unsupervised learning, may be derived statistically based on testing, and/or the like. In some examples, the remaining service life may be about 500 k when the first contact resistance between the NO terminals (or the first contact 102a and the second contact 102b) is within the second range.

In some examples, the first contact resistance between the NO terminals (or the first contact 102a and the second contact 102b) may be within a third range. The third range may be derived based on a predetermined data, may be learned such as via supervised or unsupervised learning, may be derived statistically based on testing, and/or the like. For example, the third range may be 100 mΩ-1000 mΩ. In some examples, the remaining service life of the example switch 100 may be within a range that is based on a predetermined data, may be learned such as via supervised or unsupervised learning, may be derived statistically based on testing, and/or the like. In some examples, the remaining service life may be about 100 k when the first contact resistance between the NO terminals (or the first contact 102a and the second contact 102b) is within the third range.

Additionally, and/or alternatively, in some embodiments, the controller component 150 may be configured to measure a second contact resistance between the NC terminals (or the third contact 102c, and the fourth contact 102d) when the actuator 103 is released. For example, as shown in FIG. 1B, the controller component 150 may be configured to measure the second contact resistance when the actuator 103 is released and the bridge 103b of the actuator 103 is conducting the NC terminals (or the third contact 102c, and the fourth contact 102d).

In some examples, the second contact resistance between the NC terminals (or the third contact 102c, and the fourth contact 102d) may be within the first range. The first range may be derived based on a predetermined data, may be learned such as via supervised or unsupervised learning, may be derived statistically based on testing, and/or the like. For example, the first range may be 0-45 mΩ. In some examples, the remaining service life of the example switch 100 may be within a range that is based on a predetermined data, may be learned such as via supervised or unsupervised learning, may be derived statistically based on testing, and/or the like. In some examples, the remaining service life may be within a range from about 1000K to about 1500K when the second contact resistance between the NC terminals (or the third contact 102c, and the fourth contact 102d) is within the first range.

In some examples, the second contact resistance between the NC terminals (or the third contact 102c, and the fourth contact 102d) may be within the second range. The second range may be derived based on a predetermined data, may be learned such as via supervised or unsupervised learning, may be derived statistically based on testing, and/or the like. For example, the second range may be 45 mΩ-100 mΩ. In some examples, the remaining service life of the example switch 100 may be within a range that is based on a predetermined data, may be learned such as via supervised or unsupervised learning, may be derived statistically based on testing, and/or the like. In some examples, the remaining service life may be about 500 k when the second contact resistance between the NC terminals (or the third contact 102c, and the fourth contact 102d) is within the second range.

In some examples, the second contact resistance between the NC terminals (or the third contact 102c, and the fourth contact 102d) may be within the third range. The third range may be derived based on a predetermined data, may be learned such as via supervised or unsupervised learning, may be derived statistically based on testing, and/or the like. For example, the third range may be 100 mΩ-1000 mΩ. In some examples, the remaining service life of the example switch 100 may be within a range that is based on a predetermined data, may be learned such as via supervised or unsupervised learning, may be derived statistically based on testing, and/or the like. In some examples, the remaining service life may be about 100 k when the second contact resistance between the NC terminals (or the third contact 102c, and the fourth contact 102d) is within the third range.

In some embodiments, the example switch 100 may further comprise an indicator 160, configured to be electrically communicating and/or coupled with the controller component 150. In some examples, the indicator 160 may comprise one or more light emitting diodes (“LED”), laser emitting diodes, and/or the like. For example, the controller component 150 may control the indicator 160 may to illuminate in a corresponding color based on the remaining service life of the example switch 100. Alternatively or additionally, other sound producing devices or displays may be used, such as a speaker, a screen, or the like.

In some examples, in an instance in which the first contact resistance between the NO terminals (or the first contact 102a and the second contact 102b) is in the first range, the controller component 150 may control the indicator 160 to illuminate in a first color. For example, the first color may be green. In some examples, in an instance in which the second contact resistance between the NC terminals (or the third contact 102c and the fourth contact 102d) is in the first range, the controller component 150 may control the indicator 160 to illuminate in the first color.

In some examples, in an instance in which the first contact resistance between the NO terminals (or the first contact 102a and the second contact 102b) is in the second range, the controller component 150 may control the indicator 160 to illuminate in a second color. For example, the second color may be orange. In some examples, in an instance in which the second contact resistance between the NC terminals (or the third contact 102c and the fourth contact 102d) is in the second range, the controller component 150 may control the indicator 160 to illuminate in the second color.

In some examples, in an instance in which the first contact resistance between the NO terminals (or the first contact 102a and the second contact 102b) is in the third range, the controller component 150 may control the indicator 160 to illuminate in a third color. For example, the third color may be yellow. In some examples, in an instance in which the second contact resistance between the NC terminals (or the third contact 102c and the fourth contact 102d) is in the third range, the controller component 150 may control the indicator 160 to illuminate in the third color.

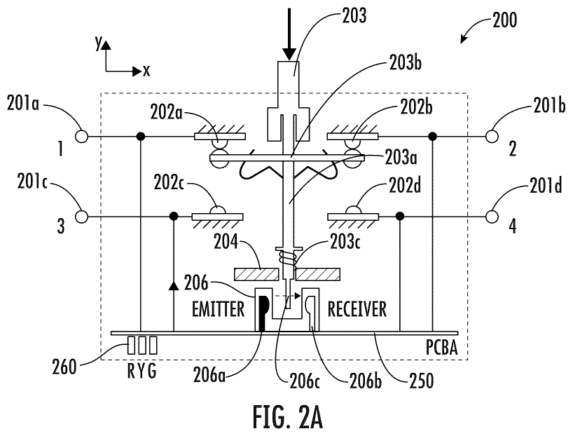

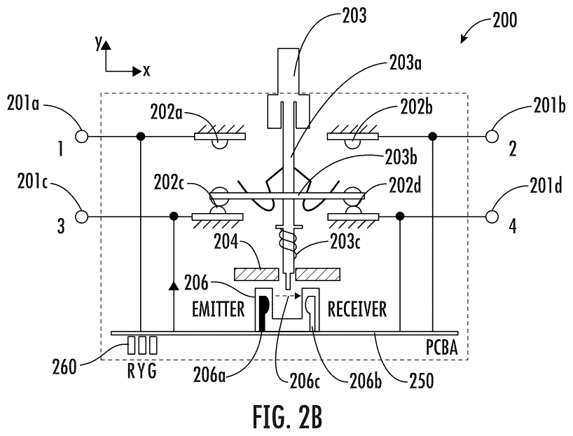

Referring now to FIG. 2A and FIG. 2B, example diagrams illustrating an example switch 200 in accordance with some example embodiments described herein are provided. As illustrated in FIG. 2A and FIG. 2B, the example switch 200 may comprise a first terminal 201a, a second terminal 201b, a first contact 202a electrically connected with the first terminal 201a, a second contact 202b electrically connected with the second terminal 201b.

In some embodiments, the example switch 200 may further comprise a third terminal 201c, a fourth terminal 201d, a third contact 202c electrically connected with the third terminal 201c, a fourth contact 202d electrically connected with the fourth terminal 201d.

In some embodiments, the example switch 200 may further comprise an actuator 203 and a guiding element 204. For example, the actuator 203 may be confined to move through an aperture (e.g., a slot, a groove, or the like) of the guiding element 204. In some examples, the actuator 203 may comprise a pin 203a, a bridge 203b fixed on the pin 203a, and a spring 203c. For example, the spring 203c may be positioned adjacent to the pin 203a and may operate to facilitate movement of the actuator 203. For example, the actuator 203 may be configured to move vertically (e.g., in a y direction).

In some embodiments, the guiding element 204 may be positioned adjacent to one end of the pin 203a.

In some examples, the first terminal 201a and the second terminal 201b may be NO terminals. For example, the first terminal 201a and the second terminal 201b may be normally open, such that no current can flow between the first terminal 201a and the second terminal 201b until the bridge 203b of the actuator 203 is conducting the first contact 202a and the second contact 202b.

In some examples, the third terminal 201c and the fourth terminal 201d may be NC terminals. For example, the third terminal 201c and the fourth terminal 201d may be normally closed, such that a current can flow between the third terminal 201c and the fourth terminal 201d until the bridge 203b of the actuator 203 is disconnected with the third contact 202c and the fourth contact 202d.

In some examples, the actuator 203 may be configured to move vertically (e.g., in a y direction) to conduct at least one of the NO terminals and the NC terminals.

In some examples, as shown in FIG. 2A, the bridge 203b may be in contact with NO terminals (or the first contact 202a and the second contact 202b) in an instance in which the actuator 203 is pressed, such that the bridge 203b of the actuator 203 is conducting the NO terminals (or the first contact 202a and the second contact 202b). In some examples, as shown in FIG. 2B, the bridge 203b may be in contact with the NC terminals (or the third contact 202c and the fourth contact 202d) in an instance in which the actuator 203 is released, such that the bridge 203b of the actuator 203 is conducting the NC terminals (or the third contact 202c and the fourth contact 202d).

In some examples, repeatable switching actions (e.g., pressing and releasing) may be performed by pressing the actuator 203 and releasing the actuator 203.

In some embodiments, the example switch 200 may further comprise a controller component 250, such as a printed circuit board assembly (PCBA), to communicate with the first contact 202a, the second contact 202b, the third contact 202c, and the fourth contact 202d. An example PCBA may be or include epoxy, ceramic, alumina, LCPs, combinations thereof, and/or the like. For example, wire may be utilized to electrically connect the first contact 202a, the second contact 202b, the third contact 202c, and the fourth contact 202d to the PCBA.

In some embodiments, the controller component 250 may be configured to count pressing times that the actuator 203 is pressed. For example, the controller component 250 may record a historical pressing times that the actuator 203 may have been pressed. In some example, the historical pressing times may increase by one each time the actuator 203 is pressed.

In some embodiments, the example switch 200 may further comprise a sensor 206 located adjacent to the actuator 203. In some examples, the sensor 206 may sense and/or detect the actuator 203 in an instance in which the actuator 203 is pressed.

In some examples, the sensor 206 may be an optoelectronic switch. For example, the sensor 206 may comprise an emitter 206a and a receiver 206b. For example, the emitter 206a may operate by generating a beam (e.g., an electromagnetic beam, visible light beam, infrared beam, and/or the like) and directing the beam to the receiver 206b. For example, the receiver 206b may receive the beam from the emitter 206a and detect any interruption of the beam in an instance in which the actuator 203 is pressed.

For examples, as shown in FIG. 2A, in an instance in which the actuator 203 is pressed, one end of the pin 203a of the actuator 203 may be positioned in an optical path 206c of the beam between the emitter 206a and the receiver 206b, such that an interruption of the beam from the emitter 206a to the receiver 206b may be detected.

For examples, as shown in FIG. 2B, in an instance in which the actuator 203 is released, the one end of the pin 203a of the actuator 203 may be positioned out of the optical path 206c of the beam between the emitter 206a and the receiver 206b, such that no interruption of the beam from the emitter 206a to the receiver 206b is detected.

In some examples, the sensor 206 may be in communication with and/or electrically coupled with the controller component 250 to count pressing times that the actuator 203 is pressed. As is described herein, historical pressing times may be derived based on a predetermined data, may be learned such as via supervised or unsupervised learning, may be derived statistically based on testing, and/or the like. Similarly, a remaining service life may be derived based on a predetermined data, may be learned such as via supervised or unsupervised learning, may be derived statistically based on testing, and/or the like.

In some examples, the historical pressing times may be within a first range. For example, the first range may be 0-1000K. For example, a remaining service life of the example switch 200 may be within a range from about 1000K to about 2000K.

In some examples, the historical pressing times may be within a second range. For example, the second range may be 1000 k-1500 k. For example, the remaining service life of the example switch 200 may be within a range from about 500K to about 1000K.

In some examples, the historical pressing times may be within a third range. For example, the third range may be 1500 k-2000 k. For example, the remaining service life of the example switch 200 may be within a range from about 0 to about 500K.

As is described herein, the first range, the second range, and the third range may be derived based on a predetermined data, may be learned such as via supervised or unsupervised learning, may be derived statistically based on testing, and/or the like.

In some embodiments, the example switch 200 may further comprise an indicator 260, configured to be electrically communicating and/or coupled with the controller component 250. In some examples, the indicator 260 may comprise one or more light emitting diodes (“LED”), laser emitting diodes, and/or the like. For example, the controller component 250 may control the indicator 260 may to illuminate in a corresponding color based on the remaining service life of the example switch 100.

In some examples, in an instance in which the historical pressing times is within the first range, the controller component 250 may control the indicator 260 to illuminate in a first color. For example, the first color may be green.

In some examples, in an instance in which the historical pressing times is within the second range, the controller component 250 may control the indicator 260 to illuminate in a second color. For example, the first color may be orange.

In some examples, in an instance in which the historical pressing times is within the second range, the controller component 250 may control the indicator 260 to illuminate in a second color. For example, the first color may be orange.

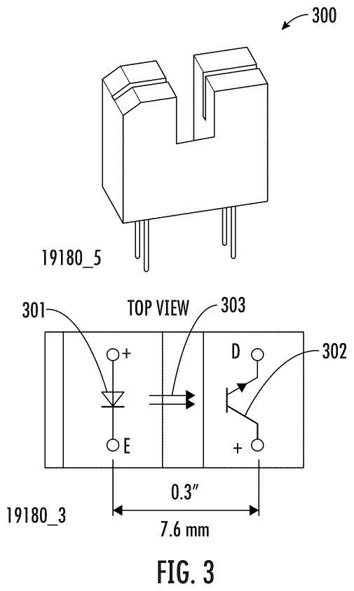

Referring now to FIG. 3, an example electrical diagram illustrating an example sensor 300 in accordance with some example embodiments described herein is provided.

As illustrated in FIG. 3, in some examples, the example sensor 300 may be an optoelectronic switch. For example, the example sensor 300 may comprise an emitter 301 and a receiver 302. For example, the emitter 301 may operate by generating a beam (e.g., an electromagnetic beam, visible light beam, infrared beam, and/or the like) and directing the beam to the receiver 302. For example, the receiver 302 may receive the beam from the emitter 301 and detect any interruption of the beam.

In some embodiments, the emitter 301 and the receiver 302 may be positioned side by side along an optical path 303 of the beam.

In some examples, components of the example sensor 300 described herein may correspond to the components of the sensor 206 as described in FIG. 2A and FIG. 2B.

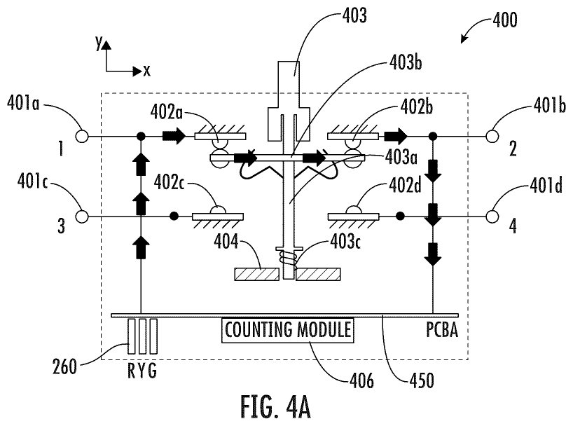

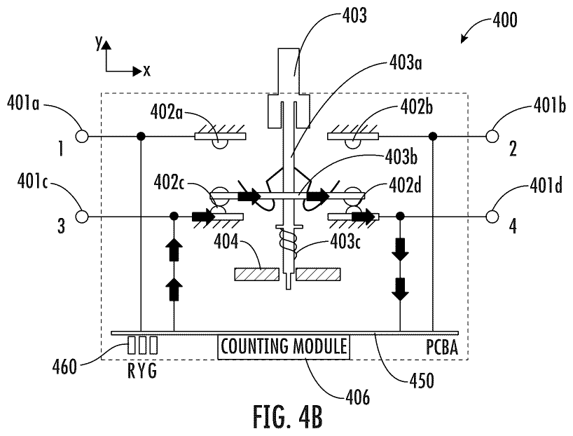

Referring now to FIG. 4A and FIG. 4B, example diagrams illustrating a switch 400 in accordance with some example embodiments described herein are provided. As illustrated in FIG. 4A and FIG. 4B, the example switch 400 may comprise a first terminal 401a, a second terminal 401b, a first contact 402a electrically connected with the first terminal 401a, a second contact 402b electrically connected with the second terminal 401b.

In some embodiments, the example switch 400 may further comprise a third terminal 401c, a fourth terminal 401d, a third contact 402c electrically connected with the third terminal 401c, a fourth contact 402d electrically connected with the fourth terminal 401d.

In some embodiments, the example switch 400 may further comprise an actuator 403 and a guiding element 404. For example, the actuator 403 may be confined to move through an aperture (e.g., a slot, a groove, or the like) of the guiding element 404. In some examples, the actuator 403 may comprise a pin 403a, a bridge 403b fixed on the pin 403a, and a spring 403c. For example, the spring 403c may be positioned adjacent to the pin 403a and may operate to facilitate movement of the actuator 403. For example, the actuator 403 may be configured to move vertically (e.g., in a y direction).

In some embodiments, the guiding element 404 may be positioned adjacent to one end of the pin 403a.

In some examples, the first terminal 401a and the second terminal 401b may be NO terminals. For example, the first terminal 401a and the second terminal 401b may be normally open, such that no current can flow between the first terminal 401a and the second terminal 401b until the bridge 403b of the actuator 403 is conducting the NO terminals (or the first contact 402a and the second contact 402b).

In some examples, the third terminal 401c and the fourth terminal 401d may be NC terminals. For example, the third terminal 401c and the fourth terminal 401d may be normally closed, such that a current can flow between the third terminal 401c and the fourth terminal 401d until the bridge 403b of the actuator 403 is disconnected with the NC terminals (or the third contact 402c and the fourth contact 402d).

In some examples, the actuator 403 may be configured to move vertically (e.g., in a y direction) to conduct at least one of the NO terminals and the NC terminals.

In some examples, as shown in FIG. 4A, the bridge 403b may be in contact with the NO terminals (or the first contact 402a and the second contact 402b) in an instance in which the actuator 403 is pressed, such that the bridge 403b of the actuator 403 is conducting the NO terminals (or the first contact 402a and the second contact 402b).

In some examples, as shown in FIG. 4B, the bridge 403b may be in contact with the NC terminals (or the third contact 402c and the fourth contact 402d) in an instance in which the actuator 403 is released, such that the bridge 403b of the actuator 403 is conducting the NC terminals (or the third contact 402c and the fourth contact 402d).

In some examples, repeatable switching actions (e.g., pressing and releasing) may be performed by pressing the actuator 403 and releasing the actuator 403.

In some embodiments, the example switch 400 may further comprise a controller component 450, such as a printed circuit board assembly (PCBA), to communicate with the first contact 402a, the second contact 402b, the third contact 402c, and the fourth contact 402d. An example PCBA may be or include epoxy, ceramic, alumina, LCPs, combinations thereof, and/or the like. For example, wire may be utilized to electrically connect the first contact 402a, the second contact 402b, the third contact 402c, and the fourth contact 402d to the PCBA.

In some embodiments, the example switch 400 may further comprise a counting module 406 configured to communicate and/or be electrically coupled with the controller component 450. For example, the counting module 406 may be configured to count times that the actuator conducts the NO terminals or count times that the actuator conducts the NC terminals.

In some embodiments, the counting module 406 may be configured to count times that the bridge 403b may be in contact with the NO terminals (or the first contact 402a and the second contact 402b). For example, the controller component 450 may record a historical conducting times that the actuator 403 has been pressed, such that the bridge 403b is in contact with the NC terminals (or the first contact 402a and the second contact 402b). In some example, the historical conducting times may increase by one each time the actuator 403 is pressed.

Additionally or alternatively, in some embodiments, the counting module 406 may be configured to count times that the bridge 403b is in contact with the NC terminals (or the third contact 402c and the fourth contact 402d). For example, the controller component 450 may record a historical conducting times that the actuator 403 has been released, such that the bridge 403b is in contact with the NC terminals (or the third contact 402c and the fourth contact 402d). In some example, the historical conducting times may increase by one each time the actuator 403 is released. As is described herein, historical conducting times may be derived based on a predetermined data, may be learned such as via supervised or unsupervised learning, may be derived statistically based on testing, and/or the like. Similarly, a remaining service life may be derived based on a predetermined data, may be learned such as via supervised or unsupervised learning, may be derived statistically based on testing, and/or the like.

In some examples, the historical conducting times may be within a first range. For example, the first range may be 0-1000K. For example, a remaining service life of the example switch 400 may be within a range from about 1000K to about 2000K.

In some examples, the historical conducting times may be within a second range. For example, the second range may be 1000 k-1500 k. For example, the remaining service life of the example switch 400 may be within a range from about 500K to about 1000K.

In some examples, the historical conducting times may be within a third range. For example, the third range may be 1500 k-2000 k. For example, the remaining service life of the example switch 400 may be within a range from about 0 to about 500K.

In some embodiments, the example switch 400 may further comprise an indicator 460, configured to be electrically communicating and/or coupled with the controller component 450. In some examples, the indicator 460 may comprise one or more light emitting diodes (“LED”), laser emitting diodes, and/or the like. For example, the controller component 450 may control the indicator 460 may to illuminate in a corresponding color based on the remaining service life of the example switch 400.

In some examples, in an instance in which the historical conducting times is within the first range, the controller component 450 may control the indicator 460 to illuminate in a first color. For example, the first color may be green.

In some examples, in an instance in which the historical conducting times is within the second range, the controller component 450 may control the indicator 460 to illuminate in a second color. For example, the first color may be orange.

In some examples, in an instance in which the historical conducting times is within the second range, the controller component 450 may control the indicator 460 to illuminate in a second color. For example, the first color may be orange.

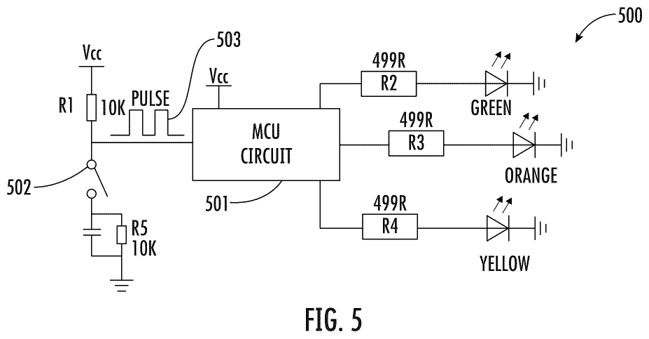

Referring now to FIG. 5, an example electrical diagram illustrating an example switch 500 in accordance with some example embodiments described herein is provided.

As illustrated in FIG. 5, in some examples, the example switch 500 may comprise a microcontroller unit (MCU) circuit 501, configured to communicate and/or be coupled with terminals 502 of the example switch 500. For example, the terminals 502 of the example switch 500 may be the NO terminals (e.g., as shown in FIG. 4A, the NO terminals 401a and 401b) and/or the NC terminals (e.g., as shown in FIG. 4B, the NC terminals 401c and 401d. For example,

In some embodiments, the MCU circuit 501 may operate by monitoring and/or detecting a voltage level of a signal 503 between the NO terminals 401a and 401b (or the first contact 402a and the second contact 402b). For example, in an instance in which the example switch 500 closes (e.g., the bridge 403b is in contact with the NO terminals (or the first contact 402a and the second contact 402b)), the voltage level pulse may drop to half of Vcc. For example, the MCU circuit 501 may count times that the voltage level pulse drops to half of Vcc. In some examples, the controller component 450 may communicate with the MCU circuit 501 and determine the historical conducting times that the actuator 403 has been pressed.

In some embodiments, the MCU circuit 501 may operate by monitoring and/or detecting a voltage level of the signal 503 between the NC terminals 401c and 401d (or the third contact 402c and the fourth contact 402d). For example, in an instance in which the example switch 500 opens (e.g., the bridge 403b is in contact with the NC terminals (or the third contact 402c and the fourth contact 402d)), the voltage level pulse may jump to Vcc. For example, the MCU circuit 501 may count times that the voltage level pulse jump to Vcc. In some examples, the controller component 450 may communicate with the MCU circuit 501 and determine the historical conducting times that the actuator 403 has been released.

In some examples, the MCU circuit 501 described herein may correspond to the counting module 406 as described in FIG. 4A and FIG. 4B.

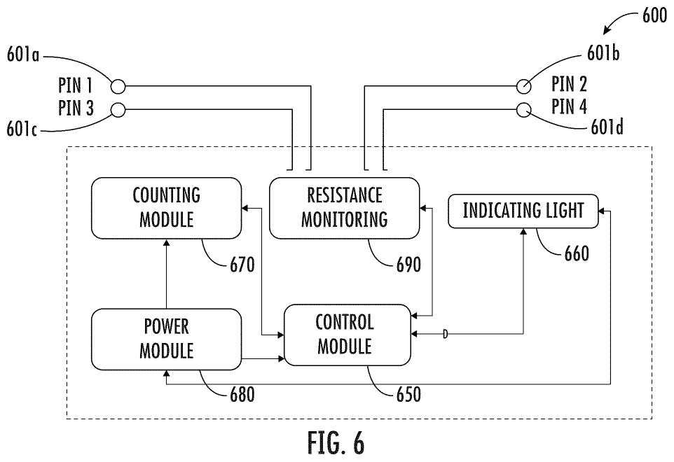

Referring now to FIG. 6, an example block diagram illustrating an example switch 600 in accordance with some example embodiments described herein is provided.

As illustrated in FIG. 6, in some examples, the example switch 600 may comprise NO terminals (e.g., 601a and 601b), NC terminals (e.g., 601c and 601d) a controller component 650, an indicator 660, a counting module 670, and a power module 680. controller component 450,

In some examples, the controller component 650 may be configured to communicate or be coupled with the NO terminals (e.g., 601a and 601b), the NC terminals (e.g., 601c and 601d), the indicator 660, the counting module 670, and the power module 680. In some examples, the power module 680 may provide power supply to the controller component 650, the indicator 660, and the counting module 670.

In some examples, the indicator 660 may be configured to be electrically communicating and/or coupled with the controller component 650. In some examples, the indicator 660 may comprise one or more light emitting diodes (“LED”), laser emitting diodes, and/or the like. For example, indicator 160 may be controlled to be illuminated with a corresponding color based on the remaining service life of the example switch 600.

In some examples, the counting module 670 may be configured to count times that the NO terminals (e.g., 601a and 601b) were conducting. In some examples, the counting module 670 may be configured to count times that the NC terminals (e.g., 601c and 601d) were conducting.

In some embodiments, the example switch 600 may further comprise a resistance monitoring module 690. In some examples, the controller component 650 may be further configured to communicate or be coupled with the resistance monitoring module 690. For example, the resistance monitoring module 690 may be configured to measure a first contact resistance between the NO terminals (e.g., 601a and 601b) and/or a second contact resistance between the NC terminals (e.g., 601c and 601d). For example, the controller component 650 may be configured to determine a remaining service life of the example switch 600 based on the first contact resistance between the NO terminals (e.g., 601a and 601b) and/or the second contact resistance between the NC terminals (e.g., 601c and 601d).

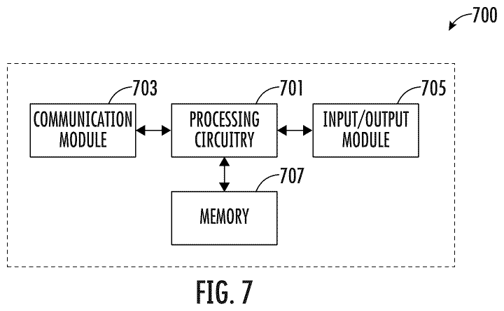

Referring now to FIG. 7, a schematic diagram depicting a controller component 700 in accordance with various embodiments of the present disclosure is provided. As shown, The controller component 700 may comprise a processing circuitry 701, a communication module 703, input/output module 705, a memory 707, and/or other components configured to perform various operations, procedures, functions or the like described herein.

As shown in FIG. 7, the controller component 700 (such as the processing circuitry 701, communication module 703, input/output module 705 and memory 707) may be electrically coupled to and/or in electronic communication with other components of the example switch (e.g., the example switch 100 as shown in FIG. 1A and FIG. 1B, the example switch 200 as shown in FIG. 2A and FIG. 2B, the example switch 400 as shown in FIG. 4A and FIG. 4B, the example switch 500 as shown in FIG. 5, and the example switch 600 as shown in FIG. 6). As depicted, the other components of the example switches may exchange (e.g., transmit and receive) data with the processing circuitry 701 of the controller component 700. For example, the other components of the example switch may generate data and transmit the data to the processing circuitry 701.

The processing circuitry 701 may be implemented as, for example, various devices comprising one or a plurality of microprocessors with accompanying digital signal processors; one or a plurality of processors without accompanying digital signal processors; one or a plurality of coprocessors; one or a plurality of multi-core processors; one or a plurality of controllers; processing circuits; one or a plurality of computers; and various other processing elements (including integrated circuits, such as ASICs or FPGAs, or a certain combination thereof). In some embodiments, the processing circuitry 701 may include one or more processors. In one exemplary embodiment, the processing circuitry 701 may be configured to execute instructions stored in the memory 707 or otherwise accessible by the processing circuitry 701. When executed by the processing circuitry 701, these instructions may enable the controller component 700 to execute one or a plurality of the functions as described herein. No matter whether it is configured by hardware, firmware/software methods, or a combination thereof, the processing circuitry 701 may include entities capable of executing operations according to the embodiments of the present invention when correspondingly configured. Therefore, for example, when the processing circuitry 701 is implemented as an ASIC, an FPGA, or the like, the processing circuitry 701 may include specially configured hardware for implementing one or a plurality of operations described herein. Alternatively, as another example, when the processing circuitry 701 is implemented as an actuator of instructions (such as those that may be stored in the memory 707), the instructions may specifically configure the processing circuitry 701 to execute one or a plurality of algorithms and operations described herein.

The memory 707 may include, for example, a volatile memory, a non-volatile memory, or a certain combination thereof. Although illustrated as a single memory in FIG. 5, the memory 707 may include a plurality of memory components. In various embodiments, the memory 707 may include, for example, a hard disk drive, a random-access memory, a cache memory, a flash memory, a Compact Disc Read-Only Memory (CD-ROM), a Digital Versatile Disk Read-Only Memory (DVD-ROM), an optical disk, a circuit configured to store information, or a certain combination thereof. The memory 707 may be configured to store information, data, application programs, instructions, and etc., so that the controller component 700 can execute various functions according to the embodiments of the present disclosure. For example, in at least some embodiments, the memory 707 may be configured to cache input data for processing by the processing circuitry 701. Additionally, or alternatively, in at least some embodiments, the memory 707 may be configured to store program instructions for execution by the processing circuitry 701. The memory 707 may store information in the form of static and/or dynamic information. When the functions are executed, the stored information may be stored and/or used by the controller component 700.

The communication module 703 may be implemented as any apparatus included in a circuit, hardware, a computer program product, or a combination thereof, which is configured to receive and/or transmit data from/to another component or apparatus. The computer program product includes computer-readable program instructions stored on a computer-readable medium (for example, the memory 707) and executed by a controller component 700 (for example, the processing circuitry 701). In some embodiments, the communication module 703 (as with other components discussed herein) may be at least partially implemented as the processing circuitry 701 or otherwise controlled by the processing circuitry 701. In this regard, the communication module 703 may communicate with the processing circuitry 701, for example, through a bus. The communication module 703 may include, for example, antennas, transmitters, receivers, transceivers, network interface cards and/or supporting hardware and/or firmware/software, and is used for establishing communication with another apparatus. The communication module 703 may be configured to receive and/or transmit any data that may be stored by the memory 707 by using any protocol that can be used for communication between apparatuses. The communication module 703 may additionally or alternatively communicate with the memory 707, the input/output module 705 and/or any other component of the controller component 700, for example, through a bus.

In some embodiments, the controller component 700 may include an input/output module 705. The input/output module 705 may communicate with the processing circuitry 701 to receive instructions input by the user and/or to provide audible, visual, mechanical, or other outputs to the user. Therefore, the input/output module 705 may include supporting devices, such as a keyboard, a mouse, a display, a touch screen display, and/or other input/output mechanisms. Alternatively, at least some aspects of the input/output module 705 may be implemented on a device used by the user to communicate with the controller component 700. The input/output module 705 may communicate with the memory 707, the communication module 703 and/or any other component, for example, through a bus. One or a plurality of input/output modules and/or other components may be included in the controller component 700.

As described above and as will be appreciated based on this disclosure, embodiments of the present disclosure may include various means including entirely of hardware or any combination of software and hardware. Furthermore, embodiments may take the form of a computer program product on at least one non-transitory computer-readable storage medium having computer-readable program instructions (e.g., computer software) embodied in the storage medium. Similarly, embodiments may take the form of a computer program code stored on at least one non-transitory computer-readable storage medium. Any suitable computer-readable storage medium may be utilized including non-transitory hard disks, CD-ROMs, flash memory, optical storage devices, or magnetic storage devices.

It is to be understood that the disclosure is not to be limited to the specific embodiments disclosed, and that modifications and other embodiments are intended to be included within the scope of the appended claims. Although specific terms are employed herein, they are used in a generic and descriptive sense only and not for purposes of limitation, unless described otherwise.

What is claimed is:

1. A switch, comprising:
normally open (NO) terminals;
normally closed (NC) terminals;
an actuator, configured to conduct at least one of the NO terminals and the NC terminals;
an indicator for a remaining service life of the switch; and
a controller component, configured to:
determine the remaining service life of the switch based on a conduct resistance between at least one of the NO terminals and the NC terminals, and
control the indicator to illuminate a corresponding color based on the determined remaining service life of the switch.

2. The switch according to claim 1, wherein to determine the remaining service life of the switch, the controller component is configured to:
measure a first contact resistance between the NO terminals in an instance in which the actuator conducts the NO terminals; and
determine the remaining service life of the switch based on the first contact resistance.

3. The switch according to claim 1, wherein to determine the remaining service life of the switch, the controller component is configured to:
measure a second contact resistance between the NC terminals in an instance in which the actuator conducts the NC terminals; and
determine the remaining service life of the switch based on the second contact resistance.

4. The switch according to claim 1, wherein the actuator comprises a pin and a bridge fixed on the pin, wherein the bridge is configured to conduct the NO terminals or the NC terminals.

5. The switch according to claim 4, further comprising a guiding element, wherein the pin is configured to move through an aperture of the guiding element.

6. The switch according to claim 4, wherein the actuator further comprises a spring positioned adjacent to the pin and configured to facilitate movement of the actuator.

7. The switch according to claim 1, wherein:
the NO terminals comprise a first terminal and a second terminal, wherein the actuator conducts the first terminal and the second terminal in an instance in which the actuator conducts the NO terminals.

8. The switch according to claim 7, further comprising:
a first contact electrically connected with the first terminal; and
a second contact electrically connected with the second terminal.

9. The switch according to claim 8, wherein:
the actuator conducts the first contact and the second contact in an instance in which the actuator conducts the NO terminals.

10. The switch according to claim 1, wherein:
the NC terminals comprise a third terminal and a fourth terminal, wherein the actuator conducts the third terminal and the fourth terminal in an instance in which the actuator conducts the NC terminals.

11. The switch according to claim 10, further comprising:
a third contact electrically connected with the third terminal; and
a fourth contact electrically connected with the fourth terminal.

12. The switch according to claim 11, wherein:
the actuator conducts the third contact and the fourth contact in an instance in which the actuator conducts the NC terminals.

13. A switch, comprising:
normally open (NO) terminals;
normally closed (NC) terminals;
an actuator, configured to conduct at least one of the NO terminals and the NC terminals;
an indicator for a remaining service life of the switch;
a sensor, configured to detect the actuator in an instance in which the actuator is pressed; and
a controller component, configured to:
determine the remaining service life of the switch based on times that the actuator is pressed, and
control the indicator to illuminate a corresponding color based on the determined remaining service life of the switch.

14. The switch according to claim 13, wherein the sensor is an optoelectronic switch.

15. The switch according to claim 13, wherein the sensor comprises:
an emitter; and
a receiver, wherein the emitter is configured to generate a beam and direct the beam to the receiver, and the receiver is configured to receive the beam and detect an interruption of the beam.

16. The switch according to claim 15, wherein the interruption of the beam is detected in an instance in which the actuator is pressed.

17. The switch according to claim 13, wherein to determine the remaining service life of the switch, the controller component is configured to:
record a historical pressing times that the actuator is pressed; and
determine the remaining service life of the switch based on the historical pressing times.

18. A switch, comprising:
normally open (NO) terminals;
normally closed (NC) terminals;
an actuator, configured to conduct at least one of the NO terminals and the NC terminals;
an indicator for a remaining service life of the switch;
a counting module, configured to count times that the actuator conducts the NO terminals; and
a controller component, configured to:
determine the remaining service life of the switch based on times that actuator conducts the NO terminals, and
control the indicator to illuminate a corresponding color based on the determined remaining service life of the switch.

19. The switch according to claim 18, wherein to determine the remaining service life of the switch, the controller component is configured to:
record a historical conducting times that the actuator is conducting the NO terminals; and
determine the remaining service life of the switch based on the historical conducting times.

20. The switch according to claim 19, wherein to determine the remaining service life of the switch, the controller component is configured to:
record a historical conducting times that the actuator is conducting the NC terminals; and
determine the remaining service life of the switch based on the historical conducting times.
